(19) United States
(12) Patent Application Publication
(10) Pub. No.: US 2025/0048884 A1
(43) Pub. Date: Feb. 6, 2025

(54) DISPLAY DEVICE

(71) Applicant: Samsung Display Co., Ltd., Yongin-Si (KR)

(72) Inventors: Won Jun LEE, Yongin-si (KR); Dong Woo KIM, Yongin-si (KR); Kyeong Min PARK, Yongin-si (KR); Do Yeong PARK, Yongin-si (KR); Jin Joo HA, Yongin-si (KR)

(21) Appl. No.: 18/660,227

(22) Filed: May 10, 2024

(30) Foreign Application Priority Data
Jul. 31, 2023 (KR) 10-2023-0100102

(51) Int. Cl. H10K 59/80; H10K 59/122; H10K 59/38

(52) U.S. Cl. CPC H10K 59/80516; H10K 59/122; H10K 59/38; H10K 59/8792

(57) ABSTRACT

The present disclosure relates to a display device, and more particularly, to a display device in which lateral leakage current between adjacent pixels can be reduced so that color mixing between the adjacent pixels can be prevented. According to an embodiment of the disclosure, a substrate, a first pixel electrode and a second pixel electrode disposed on the substrate, a first light-providing layer disposed on the first pixel electrode, a second light-providing layer disposed on the second pixel electrode, a common electrode disposed on the first light-providing layer and the second light-providing layer, and a current capture layer disposed between the first pixel electrode and the second pixel electrode in a plan view.

This application claims priority from Korean Patent Application No. 10-2023-0100102 filed on Jul. 31, 2023, in the Korean Intellectual Property Office, the disclosure of which is incorporated herein by reference in its entirety.

### BACKGROUND

### 1. Field of the Disclosure

The present disclosure relates to a display device, and more particularly, to a display device in which lateral leakage current between adjacent pixels can be reduced so that color mixing between the adjacent pixels can be prevented.

### 2. Description of the Related Art

An organic light-emitting display apparatus includes display elements having luminance varying depending on electric current flowing through the display elements, for example, organic light-emitting diodes.

### SUMMARY

Aspects of the present disclosure provide a display device in which lateral leakage current between adjacent pixels is reduced so that color mixing between the adjacent pixels can be prevented.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

It should be noted that objects of the present disclosure are not limited to the above-mentioned object and other objects of the present disclosure will be apparent to those skilled in the art from the following descriptions.

According to an embodiment of the disclosure, a display device comprising a substrate; a first pixel electrode and a second pixel electrode disposed on the substrate; a first light-providing layer disposed on the first pixel electrode; a second light-providing layer disposed on the second pixel electrode; a common electrode disposed on the first light-providing layer and the second light-providing layer; and a current capture layer disposed between the first pixel electrode and the second pixel electrode in a plan view.

In an embodiment, a capture voltage applied to the current capture layer is lower than a pixel voltage applied to the first pixel electrode.

In an embodiment, the capture voltage is identical to a common voltage applied to the common electrode.

In an embodiment, the display device may further include a bank overlapping the current capture layer in a plan view and defining a first emission area of the first pixel electrode and a second emission area of the second pixel electrode.

In an embodiment, the display device may further include a light-blocking layer overlapping the current capture layer in a plan view.

In an embodiment, the display device may further include a separator disposed on the bank to overlap the light-blocking layer in a plan view.

In an embodiment, the current capture layer overlaps with the bank, the separator, and the light-blocking layer.

In an embodiment, the display device further comprising a separator overlapping the light-blocking layer. The bank may include holes formed through the bank.

In an embodiment, the display device may further include an insulating layer disposed under the bank and including grooves disposed in areas corresponding to the holes.

In an embodiment, the separation layer may fill the holes and the grooves.

In an embodiment, portions of the separation layer filling the holes and the grooves may cover sidewalls of the current capture layer.

In an embodiment, the display device may further include a first color filter overlapping the first emission area; and a second color filter overlapping the second emission area.

In an embodiment, the current capture layer may have a shape surrounding each of the first pixel electrode and the second pixel electrode, and wherein a portion of the current capture layer may be disposed between the first pixel electrode and the second pixel electrode.

In an embodiment, the current capture layer may include a first extended portion extending in a first direction and a second extended portion extending in a second direction crossing the first direction.

In an embodiment, the current capture layer may define a plurality of open areas surrounded by the first extended portion and the second extended portion, and wherein the first pixel electrode and the second pixel electrode are disposed the plurality of open areas.

In an embodiment, the current capture layer may be connected directly to at least one of the first light-providing layer and the second light-providing layer.

In an embodiment, the current capture layer may include a support layer disposed between the first pixel electrode and the second pixel electrode, and a connection layer extending from the support layer, disposed between the first light-providing layer and the second light-providing layer, and connected to at least one of the first light-providing layer and the second light-providing layer.

In an embodiment, each of the first light-providing layer and the second light-providing layer may include a plurality of light-emitting units providing lights of different colors.

According to an embodiment of the disclosure, a display device may include a substrate and a plurality of light-emitting elements disposed on the substrate. Each of the plurality of light-emitting elements may include a pixel electrode and a current capturing layer disposed on a same plane and including a same material, the current capturing layer completely surrounding the pixel electrode, a bank disposed on the pixel electrode to cover edges of the pixel electrode and on the current capturing layer to cover the current capturing layer, a light providing layer disposed on the pixel electrode, and a common electrode disposed on the light-providing layer.

In an embodiment, the bank may completely cover a top surface and sidewalls of the current capturing layer.

The details of one or more embodiments of the subject matter described in this specification are set forth in the accompanying drawings and the description below.

According to an embodiment of the present disclosure, a current capture layer (or charge capture layer) may be disposed between adjacent pixels in a display device. The current capture layer may capture charges on a current path between adjacent pixels, thereby reducing lateral leakage current between the adjacent pixels. Accordingly, it is possible to prevent color mixing between adjacent pixels.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a display device according to an exemplary embodiment of the present disclosure.

FIG. 2 is a perspective view showing a display device included in an electron device according to an embodiment of the present disclosure.

FIG. 3 is a cross-sectional view of the display device of FIG. 2 seen from the side.

FIG. 4 is a plan view showing a display layer of a display device according to an exemplary embodiment of the present disclosure.

FIG. 5 is a plan view of pixel electrodes and a dummy pixel electrode DPE of a display device according to an exemplary embodiment.

FIG. 6 is a cross-sectional view taken along line I-I′ of FIG. 5.

FIG. 7 is a view for illustrating effects of reducing lateral leakage current in a display device according to an embodiment of the present disclosure.

FIG. 8 is a cross-sectional view showing another example, taken along line I-I′ of FIG. 5.

FIG. 9 is a cross-sectional view showing another example, taken along line I-I′ of FIG. 5.

FIG. 10 is a cross-sectional view showing a structure of a display element according to an exemplary embodiment of the present disclosure.

FIGS. 11, 12, 13 and 14 are cross-sectional views illustrating structures of light-emitting elements according to exemplary embodiments.

FIG. 15 is a cross-sectional view showing an example of the organic light-emitting diode of FIG. 13.

FIG. 16 is a cross-sectional view showing an example of the organic light-emitting diode of FIG. 14.

### DETAILED DESCRIPTION OF THE EMBODIMENTS

Advantages and features of the present disclosure and methods to achieve them will become apparent from the descriptions of exemplary embodiments hereinbelow with reference to the accompanying drawings. However, the present disclosure is not limited to exemplary embodiments disclosed herein but may be implemented in various different ways. The exemplary embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various exemplary embodiments of the present disclosure may be combined partially or totally. As will be clearly appreciated by those skilled in the art, technically various interactions and operations are possible. Various exemplary embodiments can be practiced individually or in combination.

Hereinafter, exemplary embodiments of the present disclosure will be described with reference to the accompanying drawings.

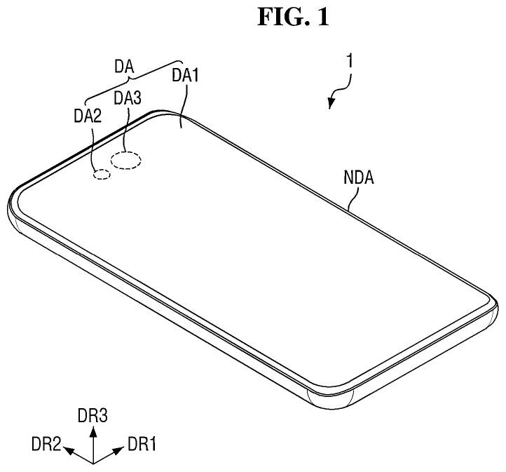

FIG. 1 is a plan view of a display device according to an exemplary embodiment of the present disclosure.

Referring to FIG. 1, an electron device 1 displays a moving image or a still image. The electron device 1 may refer to any electronic device that provides a display screen. For example, the electron device 1 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

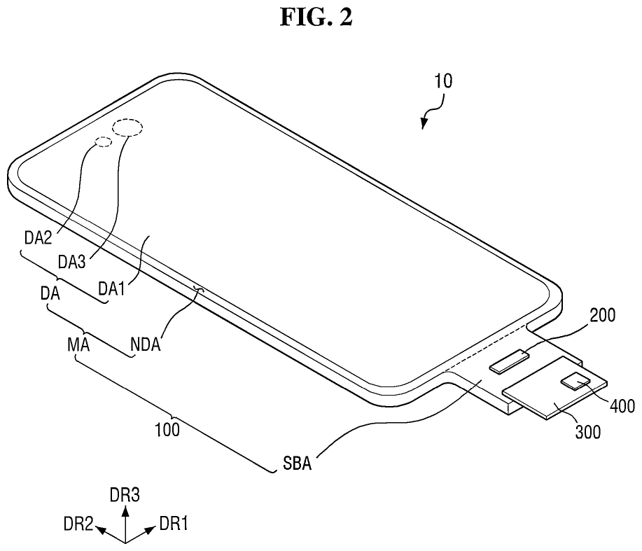

The electron device 1 may include a display device 10 (see FIG. 2) for providing a display screen. Examples of the display device may include an inorganic light-emitting diode display device, an organic light-emitting display device, a quantum-dot light-emitting display device, a plasma display device, a field emission display device, etc. In the following description, an organic light-emitting diode display device is employed as an example of the display device, but the present disclosure is not limited thereto. Any other display device may be employed as long as the technical idea of the present disclosure can be equally applied.

The shape of the electron device 1 may be modified in a variety of ways. For example, the electron device 1 may have shapes such as a rectangle with longer lateral sides, a rectangle with longer vertical sides, a square, a quadrangle with rounded corners (vertices), other polygons, a circle, etc. The shape of a display area DA of the electron device 1 may also be similar to the overall shape of the electron device 1. In the example shown in FIG. 1, the electron device 1 has a rectangular shape with the longer sides in a second direction DR2.

The electron device 1 may include the display area DA and a non-display area NDA. In the display area DA, images can be displayed. In the non-display area NDA, images are not displayed. The display area DA may be referred to as an active area, while the non-display area NDA may be referred to as an inactive area. The display area DA may generally occupy the center of the electron device 1.

The display area DA may include a first display area DA1, a second display area DA2 and a third display area DA3. In the second display area DA2 and the third display area DA3, components for implementing a variety of functions to the electronic device 1 may be disposed. In other words, the second display area DA2 and the third display area DA3 may be referred to as component areas.

FIG. 2 is a perspective view showing a display device included in an electron device according to an embodiment of the present disclosure.

Referring to FIG. 2, the electron device 1 according to the exemplary embodiment of the present disclosure may include a display device 10. The display device 10 may provide a display screen where images are displayed in the electron device 1. The display device 10 may have a shape similar to that of the electronic device 1 when viewed from the top. For example, the display device 10 may have a shape similar to a rectangle having shorter sides in the first direction DR1 and longer sides in the second direction DR2. The corners where the shorter sides in the first direction DR1 meet the longer sides in the second direction DR2 may be rounded with a predetermined curvature. It should be understood, however, that the present disclosure is not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include the display area DA including pixels for displaying images, and the non-display area NDA located around the display area DA. The display area DA may include the first display area DA1, the second display area DA2 and the third display area DA3. The display area DA may output lights from a plurality of emission areas or a plurality of open areas. For example, the display panel 100 may include a pixel circuit including switching elements, a pixel-defining layer that defines the emission areas or the open areas, and a self-light-emitting element.

For example, the self-light-emitting element may include, but is not limited to, at least one o: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be disposed on the outer side of the display area DA. The non-display area NDA may be the edge area of the main area MA of the display panel 100. The non-display area NDA may include a gate driver (not shown) that applies gate signals to gate lines, and fan-out lines (not shown) that connect the display driver 200 with the display area DA.

The subsidiary area SBA may extend from one side of the main area MA. The subsidiary area SUB may include a flexible material that can be bent, folded, or rolled. For example, when the subsidiary area SBA is bent, the subsidiary area SBA may overlap the main area MA in the thickness direction (third direction DR3). The subsidiary area SBA may include pads connected to the display driver 200 and the circuit board 300. According to another exemplary embodiment, the subsidiary area SBA may be eliminated, and the display driver 200 and the pads may be disposed in the non-display area NDA.

The display driver 200 may output control signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap with the main area MA in the thickness direction when the subsidiary area SBA is bent. For another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 300. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signal may be a pulse signal having a predetermined frequency. The touch driver 400 may determine whether there is an input and may find the coordinates of the input based on the amount of the change in the capacitance between the touch electrodes. The touch driver 400 may be implemented as an integrated circuit (IC).

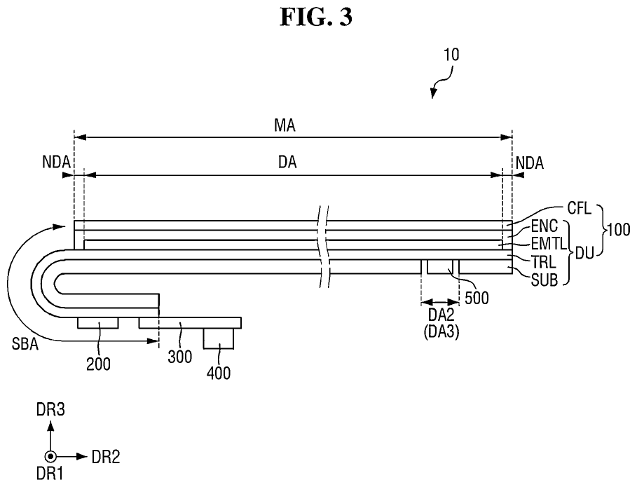

FIG. 3 is a cross-sectional view of the display device of FIG. 2.

Referring to FIG. 3, the display panel 100 may include a display layer DU and a color filter layer CFL. The display layer DU may include a substrate SUB, a transistor layer TRL, an emission material layer EMTL and an encapsulation layer ENC.

The substrate SUB may be a base substrate or a base member. The substrate SUB may be a flexible substrate that can be bent, folded, or rolled. For example, the substrate SUB may include, but is not limited to, a polymer resin such as polyimide PI. According to another exemplary embodiment, the substrate SUB may include a glass material or a metal material.

The transistor layer TRL may be disposed on the substrate SUB. The transistor layer TRL may include a plurality of transistors forming pixel circuits of pixels. The transistor layer TRL may include gate lines, data lines, voltage lines, gate control lines, fan-out lines for connecting the display driver 200 with the data lines, lead lines for connecting the display driver 200 with the pads, etc. Each of the transistors may include a semiconductor region, a source electrode, a drain electrode, and a gate electrode. For example, when the gate driver is formed on one side of the non-display area NDA of the display panel 100, the gate driver may include transistors.

The transistor layer TRL may be disposed in the display area DA, the non-display area NDA and the subsidiary area SBA. Transistors, gate lines, data lines and voltage lines in the thin-film transistor layer TRL for the pixels may be disposed in the display area DA. The gate control lines and the fan-out lines in the transistor layer TRL may be disposed in the non-display area NDA. The lead lines of the transistor layer TRL may be disposed in the subsidiary area SBA.

The emission material layer EMTL may be disposed on the transistor layer TRL. The emission material layer EMTL may include a plurality of light-emitting elements each including a first electrode, a second electrode and an emissive layer to emit light, and a pixel-defining layer for defining the pixels. The plurality of light-emitting elements in the emission material layer EMTL may be disposed in the display area DA.

According to an exemplary embodiment of the present disclosure, the emissive layer may be an organic emissive layer containing an organic material. The emissive layer may include a hole transporting layer, an organic light-emitting layer and an electron transporting layer. When the first electrode receives a voltage and the second electrode receives a cathode voltage through the transistors of the transistor layer TRL, the holes and electrons may move to the organic light-emitting layer through the hole transporting layer and the electron transporting layer, respectively, such that they combine in the organic light-emitting layer to emit light.

According to another exemplary embodiment, the light-emitting elements may include quantum-dot light-emitting diodes each including a quantum-dot emissive layer, inorganic light-emitting diodes each including an inorganic semiconductor, or micro light-emitting diodes.

The encapsulation layer ENC may cover the upper and side surfaces of the emission material layer EMTL, and can protect the emission material layer EMTL. The encapsulation layer ENC may include at least one inorganic layer and at least one organic layer for encapsulating the emission material layer EMTL.

Although not shown in the drawings, according to another embodiment, a touch layer may be further disposed on the encapsulation layer ENC. The touch layer may include a plurality of touch electrodes for sensing a user's touch by capacitive sensing, and touch lines connecting the plurality of touch electrodes with a touch driver. For example, the touch layer may sense a user's touch by mutual-capacitance sensing or self-capacitance sensing. According to another embodiment, the touch layer may be disposed on a separate substrate disposed on the display layer DU. In this instance, the substrate supporting the touch layer may be a base member encapsulating the display layer DU.

The color filter layer CFL may be disposed on the encapsulation layer ENC. The color filter layer CFL may include a plurality of color filters disposed on the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is disposed directly on the encapsulation layer ENC, the display device 10 may require no separate substrate for the color filter layer CFL. Therefore, the thickness of the display device 10 can be reduced.

In some embodiments, the display device 10 may further include an optical device 500. The optical device 500 may be disposed in the second display area DA2 or the third display area DA3. The optical device 500 may output or receive light in infrared, ultraviolet, and visible ranges. For example, the optical device 500 may be an optical sensor that senses light incident on the display device 10, such as a proximity sensor, an illuminance sensor, a camera sensor and an image sensor.

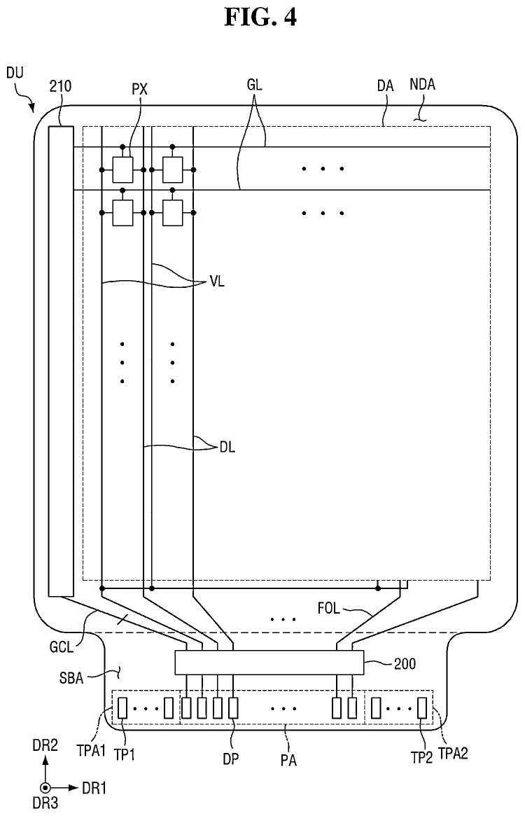

FIG. 4 is a plan view showing a display layer of a display device according to an exemplary embodiment of the present disclosure.

Referring to FIG. 4, the display layer DU may include a display area DA and a non-display area NDA.

The display area DA may be disposed at the center of display device 100. In the display area DA, a plurality of pixels PX, a plurality of gate lines GL, a plurality of data lines DL and a plurality of voltage lines may be disposed. Each of the plurality of pixels PX may be defined as the minimum unit that emits light.

The plurality of gate lines GL may supply the gate signals received from the gate driver 210 to the plurality of pixels PX. The plurality of gate lines GL may extend in the first direction DR1 and may be spaced apart from one another in the second direction DR2 intersecting the first direction DR1.

The plurality of data lines DL may supply the data voltages received from the display driver 200 to the plurality of pixels PX. The plurality of data lines DL may extend in the second direction DR2 and may be spaced apart from one another in the first direction DR1.

The plurality of voltage lines VL may supply voltage received from the display driver 200 to the plurality of pixels PX. The voltage may be at least one of a driving voltage, an initialization voltage, a reference voltage and a low-level voltage. The plurality of voltage lines VL may extend in the second direction DR2 and may be spaced apart from one another in the first direction DR1.

The non-display area NDA may surround the display area DA. In the non-display area NDA, the gate driver 210, fan-out lines FOL, and gate control lines GCL may be disposed. The gate driver 210 may generate a plurality of gate signals based on the gate control signal, and may sequentially supply the plurality of gate signals to the plurality of gate lines GL in a predetermined order.

The fan-out lines FOL may extend from the display driver 200 to the display area DA. The fan-out lines FOL may supply the data voltage received from the display driver 200 to the plurality of data lines DL.

A gate control line GCL may extend from the display driver 200 to the gate driver 210. The gate control line GCL may supply the gate control signal received from the display driver 200 to the gate driver 210.

In the subsidiary area SBA, the display driver 200, a pad area PA, and first and second touch pad areas TPA1 and TPA2 may be disposed.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the luminance of the plurality of pixels PX may be controlled. The display driver 200 may supply a gate control signal to the gate driver 210 through the gate control lines GCL.

The pad area PA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a material such as an anisotropic conductive film and a self assembly anisotropic conductive paste (SAP).

The pad area PA may include a plurality of display pads DP. The plurality of display pads DP may be connected to a graphic system through the circuit board 300. The plurality of display pads DP may be connected to the circuit board 300 to receive digital video data and may supply the digital video data to the display driver 200.

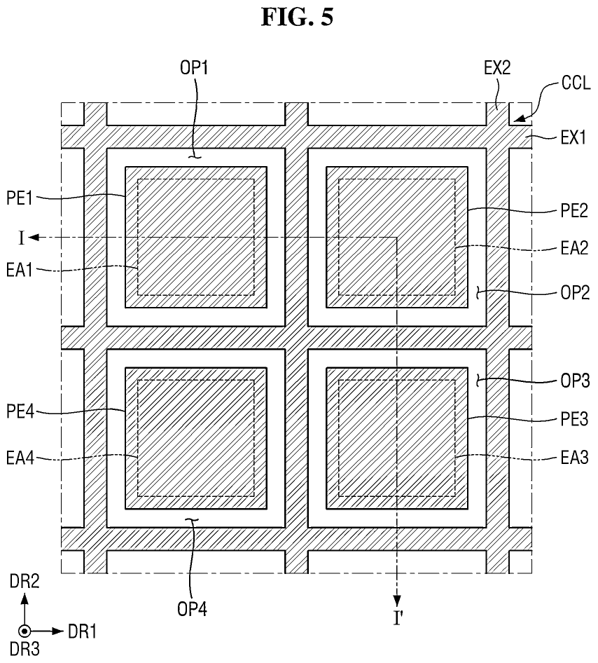

FIG. 5 is a plan view of pixel electrodes of a display device according to an exemplary embodiment.

As shown in FIG. 5, the display device may include a first pixel electrode PE1, a second pixel electrode PE2, a third pixel electrode PE3, a fourth pixel electrode PE4, and a current capture layer (or charge capture layer) CCL.

The first pixel electrode PE1, the second pixel electrode PE2, the third pixel electrode PE3 and the fourth pixel electrode PE4 may be disposed adjacent to one another. For example, the first pixel electrode PE1 and the second pixel electrode PE2 may be disposed adjacent to each other in the first direction DR1, the second pixel electrode PE2 and the third pixel electrode PE3 may be disposed adjacent to each other in the second direction DR2, and the third pixel electrode PE3 and the fourth pixel electrode PE4 may be disposed adjacent to each other in the first direction DR1.

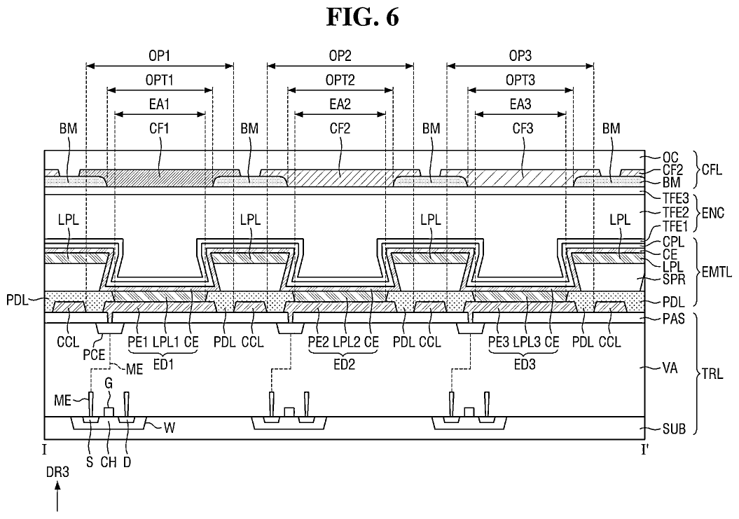

The current capture layer CCL may be disposed on the same layer as the pixel electrode. For example, the current capture layer CCL may be disposed in the same layer as the first to fourth pixel electrodes PE1 to PE4. The current capture layer CCL and the pixel electrodes may be made at the same time using the same material. For example, the current capture layer CCL and the first to fourth pixel electrodes PEL to PE4 may be made of the same material. For example, with respect to an emissive layer (e.g., LGL of FIG. 6), in the top-emission structure where light exits toward a common electrode (e.g., common electrode CE of FIG. 6), the pixel electrodes PE1 to PE4 and the current capture layer CCL may include a single layer of molybdenum (Mo), titanium (Ti), copper (Cu) or aluminum (Al), or may include a stack structure of aluminum and titanium (Ti/Al/Ti), a stack structure of aluminum and ITO (ITO/Al/ITO), an APC alloy and a stack structure of APC alloy and ITO (ITO/APC/ITO) in order to increase the reflectivity. The APC alloy is an alloy of silver (Ag), palladium (Pd) and copper (Cu).

The current capture layer CCL may be disposed between adjacent pixel electrodes, for example. For example, the current capture layer CCL may be disposed between the first pixel electrode PE1 and the second pixel electrode PE2. In addition, the current capture layer CCL may be disposed between the second pixel electrode PE2 and the third pixel electrode PE3. In addition, the current capture layer CCL may be disposed between the first pixel electrode PE1 and the fourth pixel electrode PE4. When the current capture layer CCL is disposed between every adjacent pixel electrodes, that current capture layer CCL may have a mesh shape that surrounds each of the first pixel electrode PE1, the second pixel electrode PE2, the third pixel electrode PE3 and the fourth pixel electrode PE4. In other words, the first pixel electrode PE1, the second pixel electrode PE2, the third pixel electrode PE3 and the fourth pixel electrode PE4 may be surrounded by the current capture layer CCL. For example, the first pixel electrode PE1, the second pixel electrode PE2 and the third pixel electrode PE3 may be surrounded by the current capture layer CCL when viewed from the top. In other words, the first pixel electrode PE1, the second pixel electrode PE2, the third pixel electrode PE3 and the fourth pixel electrode PE4 may be disposed in the areas defined by the current capture layer CCL (hereinafter referred to as open areas OP1, OP2, OP3 and OP4), respectively. For example, the first pixel electrode PE1 may be disposed in the first open area OP1 defined by the current capture layer CCL, the second pixel electrode PE2 may be disposed in the second open area OP2 defined by the current capture layer CCL, the third pixel electrode PE3 may be disposed in the third open area OP3 defined by the current capture layer CCL, and the fourth pixel electrode PE4 may be disposed in the fourth open area OP4 defined by the current capture layer CCL.

The current capture layer CCL may include a plurality of first extended portions EX1 extending in the first direction DR1, and a plurality of second extended portions EX2 extending in the second direction DR2. The first extended portions EX1 may cross the second extended portions EX2. The first extended portions EX1 and the second extended portions EX2 may be connected at the intersections of the first extended portions EX1 and the second extended portions EX2. The first extended portions EX1 and the second extended portions EX2 may be formed as a single piece. The above-described first pixel electrode PE1, second pixel electrode PE2, third pixel electrode PE3 and the fourth pixel electrode PE4 may be disposed in the open areas OP1, OP2, OP3 and OP4, respectively, defined by the first extended portions EX1 and the second extended portions EX2.

A part of the first pixel electrode PE1 (e.g., an edge of the first pixel electrode PE1), a part of the second pixel electrode PE2 (e.g., an edge of the second pixel electrode PE2), a part of the third pixel electrode PE3 (e.g., an edge of the third pixel electrode PE3), and a part of the fourth pixel electrode PE4 (e.g., an edge of the fourth pixel electrode PE4) may be covered by a bank PDL (see FIG. 6), which will be described later. In other words, a part of the first pixel electrode PE1 (e.g., an edge of the first pixel electrode PE1), a part of the second pixel electrode PE2 (e.g., an edge of the second pixel electrode PE2), a part of the third pixel electrode PE3 (e.g., an edge of the third pixel electrode PE3), and a part of the dummy pixel electrode DPE may partially overlap with the bank PDL described above.

Portions of the first pixel electrode PE1, the second pixel electrode PE2, the third pixel electrode PE3 and the fourth pixel electrode PE4 that are not covered by the bank PDL but are exposed may be a first emission area EA1, a second emission area EA2, a third emission area EA3, and a fourth emission area EA4, respectively. For example, the first emission area EA1 may be the emission area of a first pixel including the first pixel electrode PE1, the second emission area EA2 may be the emission area of a second pixel including the second pixel electrode PE2, the third emission area EA3 may be the emission area of a third pixel including the third pixel electrode PE3, and the fourth emission area EA4 may be the emission area of the fourth pixel including the fourth pixel electrode PE4.

FIG. 6 is a cross-sectional view taken along line I-I′ of FIG. 5.

As shown in FIG. 6, the display device 10 may include a transistor layer TRL, an emission material layer EMTL, an encapsulation layer ENC, and a color filter layer CFL.

The substrate SUB may be a silicon substrate, a germanium substrate, or a silicon-germanium substrate. The substrate SUB may be a substrate doped with first-type impurities.

A well region W may be disposed in the substrate SUB. The well W may be doped with second-type impurities. The second-type impurities may be different from the first-type impurities. For example, when the first-type impurities are p-type impurities, the second-type impurities may be n-type impurities. On the other hand, when the first-type impurities are n-type impurities, the second-type impurities may be p-type impurities.

A source region S, a drain region D and a channel region CH of a transistor TR may be disposed in the well W. For example, the source region S (or source electrode) and the drain region D (or drain electrode) of the transistor TR may be located in the well W. Each of the source region S and the drain region D may be doped with the first-type impurities. The gate electrode G of the transistor TR may cross and overlap the well W. When viewed from the top, the well W is divided into two regions by the gate electrode G. One of the two regions may be the source region S while the other may be the drain region D. In other words, in the well W, the source region S and the drain region D may be located on either side of the gate electrode G, respectively, with the gate electrode G disposed therebetween. The channel region CH of the transistor may be located where the gate electrode G overlaps with the well W.

The source region S may include a first lightly doped region having a lower impurity concentration than the other portions of the source region S. In other words, a portion of the source region S may include impurities at a lower concentration than the other portions of the source region S. The drain region D may include a second lightly doped region having a lower impurity concentration than the other portions of the drain region D. In other words, a portion of the drain region D may include impurities at a lower concentration than the other portions of the drain region D.

The first lightly doped region and the second lightly doped region may be disposed close to the channel region CH of the transistor TR. For example, the first lightly doped region may be disposed close to the channel region CH such that it overlaps with a first spacer disposed on one side of the gate electrode G, and the second lightly doped region may be disposed close to the channel region CH such that it overlaps with a second spacer disposed on the opposite side of the gate electrode G. As described above, the distance between a heavily doped region of the source region S and a heavily doped region of the drain region D may increase due to the first lightly doped region and the second lightly doped region. As a result, the length of the channel region CH may increase. Accordingly, it is possible to prevent short channel effects such as punch-through and hot carrier.

An interlayer dielectric film VA may be disposed on the substrate SUB1. The interlayer dielectric film may include a plurality of insulating films stacked in the third direction.

A passivation film PAS may be disposed on the interlayer dielectric film VA.

The emission material layer EMTL may be disposed on the passivation film PAS. The emission material layer EMTL may include, for example, a first light-emitting element ED1, a second light-emitting element ED2, a third light-emitting element ED3, and a fourth light-emitting element (e.g., a light-emitting element disposed in the fourth emission area of FIG. 5) disposed in different emission areas. For example, the first light-emitting element ED1 of the emission material layer EMTL may be disposed in the first emission area EA1, the second light-emitting element ED2 of the emission material layer EMTL may be disposed in the second emission area EA2, the third light-emitting element ED3 of the emission material layer EMTL may be disposed in the third emission area EA3, and the fourth light-emitting element of the emission material layer EMTL may be disposed in the fourth emission area EA4.

Each of the first light-emitting element ED1, the second light-emitting element ED2, the third light-emitting element ED3 and the fourth light-emitting element may emit white light.

The first light-emitting element ED1 may include a first pixel electrode PE1 (or first anode electrode), a first light-providing layer LPL1, and a common electrode CE stacked on one another in the third direction DR3.

The second light-emitting element ED2 may include a second pixel electrode PE2 (or second anode electrode), a second light-providing layer LPL2, and the common electrode CE stacked on one another in the third direction DR3.

The third light-emitting element ED3 may include a third pixel electrode PE3 (or third anode electrode), a third light-providing layer LPL3, and the common electrode CE stacked on one another in the third direction DR3.

The fourth light-emitting element ED4 may include a fourth pixel electrode PE4 (or fourth anode electrode), a fourth light-providing layer, and the common electrode CE stacked on one another in the third direction DR3.

The first to third light-providing layers LPL1, LPL2 and LPL3 and the fourth light-providing layer may include a plurality of emissive layers providing lights of different colors, and the plurality of emissive layers may be stacked on one another in the third direction DR3. Different lights from the emissive layers may be mixed to generate white light. Each of the first to third light-providing layers LPL1, LPL2 and LPL3 and the fourth light-providing layer may further include a charge generation layer.

The first pixel electrode PE1, the second pixel electrode PE2, the third pixel electrode PE3 and the fourth pixel electrode PE4 may be connected to the source region S of each transistor TR through a pixel connection electrode PCE and a metal connection layer ME.

The current capture layer CCL may receive power from the outside. For example, an edge of the current capture layer CCL may extend in at least one of the first and second directions DR1 and DR2 and may be connected to a power supply unit. The power supply unit may supply capture voltage (e.g., DC capture voltage or DC capture current) to the current capture layer CCL. Herein, the capture voltage (e.g., capture voltage) may be a voltage having lower than the voltage applied to the pixel electrode (hereinafter referred to as pixel voltage). For example, when the pixel voltage is a positive voltage, the capture voltage (e.g., DC voltage) may be a voltage lower than the minimum pixel voltage. For example, when the pixel voltage is the positive voltage, the capture voltage (e.g., DC voltage) may be the voltage of negative polarity. For example, the capture voltage may be identical to the common voltage applied to the common electrode CE.

The first pixel electrode PE1 may be disposed in line with the first emission area EA1, the second pixel electrode PE2 may be disposed in line with the second emission area EA2, the third pixel electrode PE3 may be disposed in line with the third emission area EA3, and the fourth pixel electrode PE4 may be disposed in line with the fourth emission area EA4.

The bank PDL (or pixel-defining film) may be disposed on the first pixel electrode PE1, the second pixel electrode PE2, the third pixel electrode PE3 and the fourth pixel electrode PE4.

The bank PDL may define each of the emission areas EA1, EA2, EA3 and EA4 of the pixels. To this end, the bank PDL may be disposed to expose some regions of the first pixel electrode PE1, the second pixel electrode PE2, the third pixel electrode PE3 and the fourth pixel electrode PE4 disposed on the passivation film PAS, for example. The bank PDL may cover edges of the first pixel electrode PE1, the second pixel electrode PE2, the third pixel electrode PE3 and the fourth pixel electrode PE4, and sidewalls of the current capture layer CCL. The bank PDL may be formed of an organic layer such as an acryl resin, an epoxy resin, a phenolic resin, a polyamide resin and a polyimide resin.

Separators SPR may be disposed on the bank. Each of the separators SPR may have an overhang structure in which the upper surface is wider than the lower surface. Accordingly, the separators SPR may have a reverse taper shape. The light-providing layers may be disconnected by the separators SPR having such a structure so that each of the layers is disposed in the respective emission area. In other words, during the process of depositing a light-providing material layer, the light-providing material layer is disconnected by the separators SPR, and the first light-providing layer LPL1, the second light-providing layer LPL2, the third light-providing layer LPL3 and the fourth light-providing layer, which are disposed in the different emission areas EA1, EA2, EA3 and EA4, respectively, may be disposed on the first pixel electrode PE1, the second pixel electrode PE2, the third pixel electrode PE3 and the fourth pixel electrode PE4, respectively. It should be noted that the light-providing layers LPL may also be disposed on the separators SPR. As such, the first light-providing layer LPL1, the second light-providing layer LPL2, the third light-providing layer LPL3, the fourth light-providing layer and the light-providing layers on the separators SPR may remain separated.

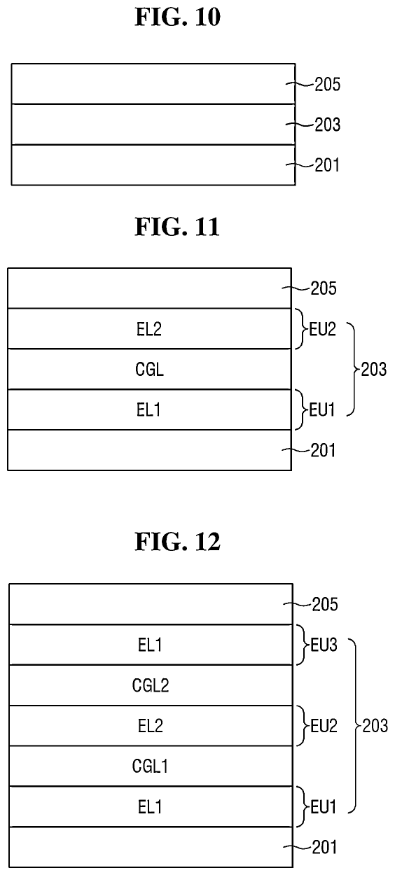

The first to third light-providing layers LPL1, LPL2 and LPL3, the fourth light-providing layer, and the light-providing layers LPL on the separators SPR may include a plurality of light-emitting units (see FIGS. 10 to 16). For example, each of the light-providing layers may include a first light-emitting unit, a second light-emitting unit, and a third light-emitting unit stacked on one another in the third direction DR3. Each of the light-emitting units may provide lights of different wavelengths. For example, the first light-emitting unit, the second light-emitting unit and the third light-emitting unit may emit lights of different colors. For example, the light-providing layer LPL may have a tandem structure in which a plurality of light-emitting units providing lights of different colors are stacked on one another in the vertical direction (e.g., in the third direction DR3).

The first light-emitting unit may be disposed on the pixel electrodes PE1, PE2, PE3 and PE4 and the separator SPR. The first light-emitting unit may include a first emissive layer, a hole transporting layer, an organic material layer, and an electron transporting layer.

The second light-emitting unit may be disposed on the first light-emitting unit. The second light-emitting unit may include a second emissive layer, a hole transporting layer, an organic material layer, and an electron transporting layer.

The third light-emitting unit may be disposed on the second light-emitting unit. The third light-emitting unit may include a third emissive layer, a hole transporting layer, an organic material layer, and an electron transporting layer.

Each of the light-emitting elements ED1, ED2 and ED3 and the fourth light-emitting element may mix light of a first color (e.g., blue) from a first light-emitting unit, light of a second color (e.g., red) from a second light-emitting unit, and light of a third color (e.g., green) from a third light-emitting unit to provide white light. For example, each of the first light-emitting element ED1, the second light-emitting element ED2, the third light-emitting element ED3 and the fourth light-emitting element may emit white light.

In addition, the first to third light-providing layers LPL1, LPL2 and LPL3, the fourth light-providing layer, and the light-providing layers LPL on the separators SPR may further include at least one charge generation layer. The charge generation layer may be disposed between adjacent light-emitting units in the third direction DR3, for example. The charge generation layer may include, for example, a first charge generation layer and a second charge generation layer stacked on one another in the third direction. In this instance, the first charge generation layer may be disposed between the first light-emitting unit and the second light-emitting unit, and the second charge generation layer may be disposed between the second light-emitting unit and the third light-emitting unit.

Each charge generating layer may include a negative-charge generating layer and a positive-charge generating layer. For example, the first charge generating layer may include a first negative-charge generating layer and a first positive-charge generating layer stacked in the third direction DR3, and the second charge generating layer may include a second negative-charge generating layer and a second positive-charge generating layer stacked in the third direction DR3.

The common electrode CE may be disposed on the first to third light-providing layers LPL1, LPL2 and LPL3, the fourth light-providing layer, and the light-providing layers LPL on the separators SPR. For example, the common electrode CE may be disposed on the light-providing layers such that it overlaps with the first pixel electrode PE1, the second pixel electrode PE2, the third pixel electrode PE3, the fourth pixel electrode PE4, the first emission area EA1, the second emission area EA2, the third emission area EA3, the fourth emission area EA4, and the bank PDL. In the top-emission structure, the common electrode CE may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode CM is formed of a semi-transmissive metal material, the light extraction efficiency can be increased by using microcavities.

A capping layer CPL may be disposed on the common electrode CE. The capping layer CPL may include an inorganic insulating material. In an exemplary embodiment, the capping layer CPL may include aluminum oxide, titanium oxide, tantalum oxide, hafnium oxide, zinc oxide, silicon oxide, silicon nitride, and/or silicon oxynitride.

An encapsulation layer ENC may be disposed on the capping layer CPL. The encapsulation layer ENC may cover the upper and side surfaces of the emission material layer EMTL, and can protect the emission material layer EMTL. The encapsulation layer ENC may include at least one inorganic layer and at least one organic layer for encapsulating the emission material layer EMTL. The encapsulation layer ENC may include one or more inorganic films TFE1 and TFE3 to prevent permeation of oxygen or moisture into the emission material layer EMTL. In addition, the encapsulation layer ENC may include at least one organic film to protect the emission material layer EMTL from particles such as dust. For example, the encapsulation layer ENC may include a first inorganic encapsulation film TFE1, an organic encapsulation film TFE2 and a second inorganic encapsulation film TFE3.

The first inorganic encapsulation film TFE1 may be disposed on the capping layer CPL, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may include multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

A light-blocking layer BM may be disposed on the encapsulation layer ENC. The light-blocking layer BM may include a plurality of holes OPT1, OPT2 and OPT3 overlapping with the emission areas EA1, EA2 and EA3, respectively. For example, the first hole OPT1 may overlap with the first emission area EA1. The second hole OPT2 may overlap with the second emission area EA2, and the third hole OPT3 may overlap with the third emission area EA3.

The area or size of the holes OPT1, OPT2 and OPT3 may be larger than that of the emission areas EA1, EA2 and EA3 defined by the bank PDL. As the holes OPT1 OPT2 and

OPT3 of the light-blocking layer BM are formed to be larger than the emission areas EA1, EA2 and EA3, the lights output from the emission areas EA1, EA2 and EA3 may be seen by a user not only from the front but also from the sides.

The light-blocking layer BM may include a light-absorbing material. For example, the light-blocking layer BM may include an inorganic black pigment or an organic black pigment. The inorganic black pigment may be, but is not limited to, carbon black, and the organic black pigment may include, but is not limited to, at least one of lactam black, perylene black, and aniline black. The light-blocking layer BM can prevent visible light from penetrating and mixing colors between the first to third emission areas EA1, EA2 and EA3 to improve the color gamut of the display device 10.

The display device 10 may include a plurality of color filters CF1, CF2 and CF3 disposed on the emission areas EA1, EA2 and EA3. The color filters CF1, CF2 and CF3 may be associated with the emission areas EA1, EA2 and EA3, respectively. For example, the color filters CF1, CF2 and CF3 may be disposed on the light-blocking layer BM including the plurality of holes OPT1, OPT2 and OPT3 associated with the emission areas EA1, EA2 and EA3, respectively. It should be noted that a color filter disposed in the fourth emission area EA4 may have the same color as the color filter disposed in the third emission area EA3, for example.

The color filters CF1, CF2 and CF3 include a first color filter CF1, a second color filter CF2 and a third color filter CF3 associated with the different emission areas EA1, EA2 and EA3, respectively. The color filters CF1, CF2 and CF3 may include a colorant such as a dye and pigment that absorbs lights in wavelength ranges other than light in a particular wavelength range, and may be disposed in areas corresponding to the lights exiting from the emission areas EA1, EA2 and EA3. For example, the first color filter CF1 may be a red color filter that is disposed to overlap with the first emission area EA1 and transmits only red light. The second color filter CF2 may be a green color filter that is disposed to overlap with the second emission area EA2 and transmits only green light. The third color filter CF3 may be a blue color filter that is disposed to overlap with the third emission area EA3 and transmits only blue light. The color filter disposed in the fourth emission area may be a blue color filter.

The color filters CF1, CF2 and CF3 may be spaced apart from one another on the light-blocking layer BM. The color filters CF1, CF2 and CF3 may cover the holes OPT1, OPT2 and OPT3 of the light-blocking layer BM and may have an area that is larger than the holes such that they are spaced apart from one another on the light-blocking layer BM. It is, however, to be understood that the present disclosure is not limited thereto. The color filters CF1, CF2 and CF3 may partially overlap with one another. The different color filters CF1, CF2 and CF3 may not overlap the emission areas EA1, EA2 and EA3 and may overlap one another on the light-blocking layer BM. In the display device 10, as the color filters CF1, CF2 and CF3 overlap one another, the intensity of reflected lights caused by external light can be reduced. Furthermore, the colors of reflected lights by external light can be controlled by adjusting the arrangement, shape and area of the color filters CF1, CF2 and CF3 when viewed from the top.

An overcoat layer OC may be disposed on the color filters CF1, CF2 and CF3 to provide upper ends of the color filters CF1, CF2 and CF3. The overcoat layer OC may be a colorless light-transmitting layer having no color in the visible light band. For example, the overcoat layer OC may include a colorless light-transmitting organic material such as an acryl-based resin.

It should be noted that the above-described current capture layer CCL may be overlapped with, for example, the bank PDL, the separator SPR, and the light-blocking layer BM in a plan view.

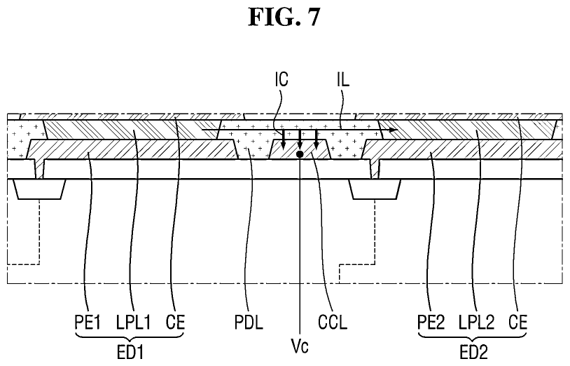

FIG. 7 is a view for illustrating effects of reducing lateral leakage current in a display device according to an embodiment of the present disclosure.

As shown in FIG. 7, a current capture layer CCL may be disposed between a first light-providing layer LPL1 disposed on a first pixel electrode PE1 and a second light-providing layer LPL2 disposed on a second pixel electrode PE2. The current capture layer CCL can reduce the amount of lateral leakage current IL that may flow from the first light-providing layer LPL1 to the second light-providing layer LPL2. For example, when a capture voltage Vc (e.g., negative DC voltage) is applied to the current capture layer CCL as a bias voltage, holes may be accumulated on each of the surface of the first light-providing layer LPL1 (e.g., an emissive layer of the first light-providing layer LPL1), and the surface of the second light-providing layer LPL2 (e.g., an emissive layer of the second light-providing layer LPL2). These holes can capture electrons of lateral leakage current IL. For example, a current path from the first light-providing layer LPL1 to the current capture layer CCL may be formed by the current capture layer CCL, and thus the capture current IC may flow along the current path. In other words, at least a part of the lateral leakage current IL (e.g., current IC) may flow to the current capture layer CCL along the above-described current path. As a result, the lateral leakage current IL flowing to adjacent pixels can be reduced, and thus color mixing between adjacent pixels can be prevented.

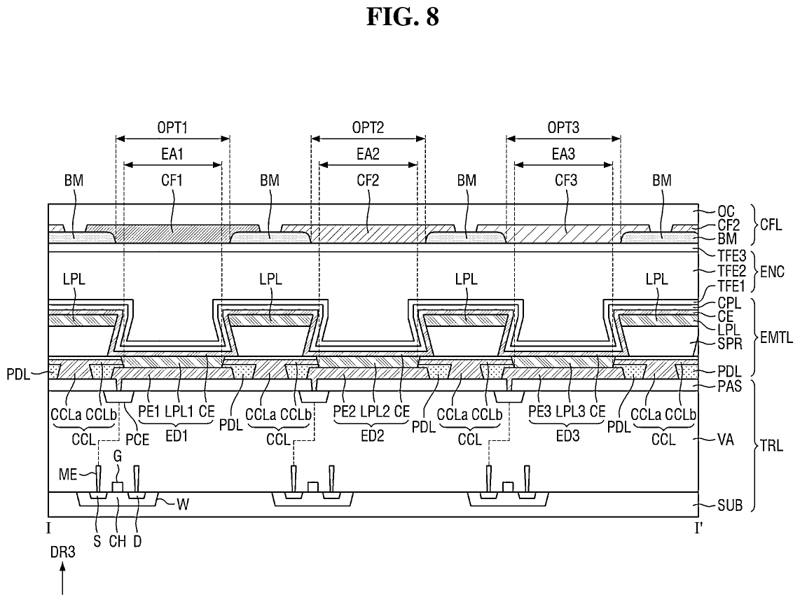

FIG. 8 is a cross-sectional view showing another example, taken along line I-I′ of FIG. 5.

A display device 10 of FIG. 8 is different from the display device 10 of FIG. 6 in that a current capture layer CCL is directly connected to (or in contact with) a pixel electrode on the bank PDL. The description will focus on the difference.

As shown in FIG. 8 the current capture layer CCL may be in contact with adjacent pixel electrodes (e.g., the first pixel electrode PE1, the second pixel electrode PE2 and the third pixel electrode PE3.

As an example, the current capture layer CCL may include a support layer CCLa and a connection layer CCLb.

The support layer CCLa of the current capture layer CCL may be disposed between adjacent pixel electrodes. For example, the support layer CCLa may be disposed between the first pixel electrode PE1 and the second pixel electrode PE2.

The connection layer CCLb of the current capture layer CCL may extend from the support layer CCLa toward the first pixel electrode PE1 and the second pixel electrode PE2 to be connected to the first pixel electrode PE1 and the second pixel electrode PE2. The connection layer CCLb and the support layer CCLa may be formed as one body. The connection layer CCLb may be disposed between adjacent light-providing layers. For example, the connection layer CCLb may be disposed between the first light-providing layer LPL1 and the second light-providing layer LPL2. The connection layer CCLb may extend to adjacent light-providing layers to be connected directly to (or in contact with) the light-providing layers. For example, the connection layer CCLb may be connected directly to (or in contact with) the first light-providing layer LPL1 and the second light-providing layer LPL2.

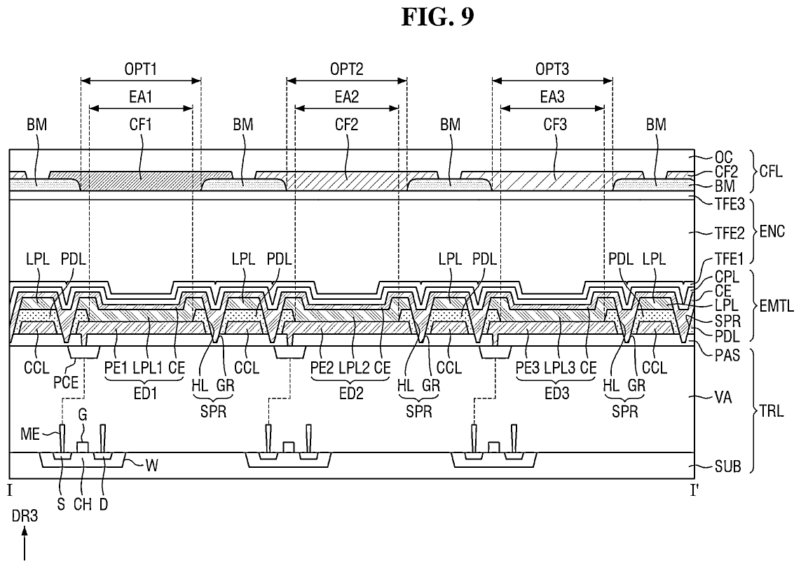

FIG. 9 is a cross-sectional view showing another example, taken along line I-I′ of FIG. 5.

A display device 10 of FIG. 9 is different from the display device 10 of FIG. 6 in that separators SPR have a trench structure. The description will focus on the difference.

As shown in FIG. 9, each of the bank PDL may include holes HL formed through the bank PDL in the third direction DR3 and an insulating film (e.g., a passivation layer PAS) may include grooves GR in areas corresponding to the holes HL. The groove GR of each of the separators SPR may be formed, for example, in an insulating film (e.g., a passivation layer PAS) under the bank PDL.

The separators SPR of FIG. 9 may be disposed between adjacent pixel electrodes and the current capture layer CCL, for example. The separators SPR of FIG. 9 may have a shape surrounding the pixel electrodes and the current capture layer CCL.

Other structures of light-emitting elements (e.g., the light-emitting elements ED1, ED2 and ED3 of FIG. 6) will be described with reference to FIGS. 10 to 16.

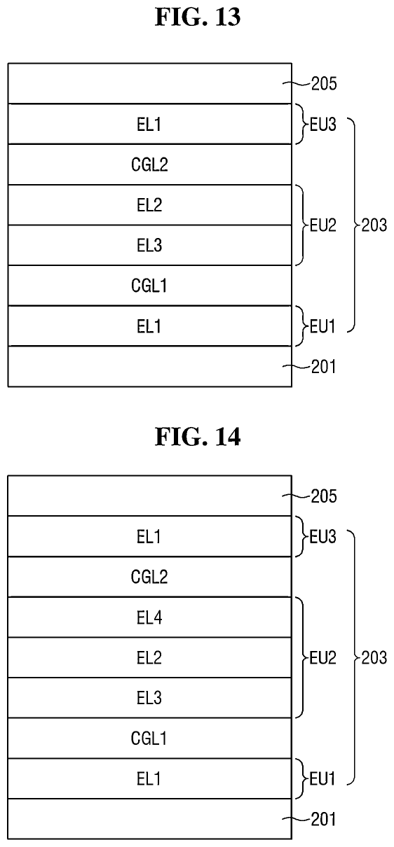

FIG. 10 is a cross-sectional view showing a structure of a display element according to an embodiment of the present disclosure. FIGS. 11 to 14 are cross-sectional views illustrating structures of light-emitting elements according to embodiments.

Referring to FIG. 10, a light-emitting element (e.g., an organic light-emitting diode) according to an exemplary embodiment may include a pixel electrode 201, a common electrode 205, and a light-providing layer 203 disposed between the pixel electrode 201 and the common electrode 205. The pixel electrode 201 may be one of the first pixel electrode PE1, the second pixel electrode PE2, the third pixel electrode PE3 and the fourth pixel electrode PE4 described above. In addition, the common electrode 205 may be the above-described common electrode CE. In addition, the light-providing layer 203 may be one of the above-described first to third light-providing layers LPL1, LPL2 and LPL3, the fourth light-providing layer, and the light-providing layers LPL disposed on the separators SPR.

The pixel electrode 201 may include a transparent conductive oxide such as indium tin oxide (ITO), indium zinc oxide (IZO), zinc oxide (ZnO), indium oxide (In₂O₃), indium gallium oxide (IGO) and aluminum zinc oxide (AZO). The pixel electrode 201 may include a reflective layer containing silver (Ag), magnesium (Mg), aluminum (Al), platinum (Pt), palladium (Pd), gold (Au), nickel (Ni), neodymium (Nd), iridium (Ir), chrome (Cr) or a compound thereof. For example, the pixel electrode 201 may have a three-layer structure of ITO/Ag/ITO.

The common electrode 205 may be disposed on the light-providing layer 203. The common electrode 205 may include a conductor having a low work function, an alloy, an electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a transflective electrode, or a reflective electrode.

The light-providing layer 203 may include a polymer or a low molecular weight organic material that emits light of a predetermined color. In addition to a variety of organic materials, the light-providing layer 203 may further include metal-containing compounds such as organometallic compounds, inorganic materials such as quantum dots, etc.

According to the exemplary embodiment, the light-providing layer 203 may include an emissive layer and a first functional layer and a second functional layer respectively disposed under and over the emissive layer. The first functional layer may include, for example, a hole transport layer HTL or may include a hole transport layer and a hole injection layer HIL. The second functional layer is an optional element disposed on the emissive layer. For example, the light-providing layer 203 may or may not include the second functional layer. The second functional layer may include an electron transport layer ETL and/or an electron injection layer EIL.

According to the exemplary embodiment, the light-providing layer 203 may include two or more emitting units sequentially stacked between the pixel electrode 201 and the common electrode 205, and a charge generation layer CGL disposed between adjacent emitting units. When the light-providing layer 203 includes the emitting units and the charge generation layer, the light-emitting element (e.g., organic light-emitting diode) may have a tandem structure. The light-emitting element (e.g., an organic light-emitting diode) can improve the color purity and the emission efficiency by employing a stack structure of a plurality of emitting units.

One emitting unit may include an emissive layer, and a first functional layer and a second functional layer respectively disposed under and over the emissive layer. The charge generation layer CGL may include a negative charge generation layer and a positive charge generation layer. The emission efficiency of an organic light-emitting diode, which is a tandem light-emitting element having a plurality of emissive layers, can be further increased by the negative charge generating layer and the positive charge generating layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

According to the exemplary embodiment, as shown in FIG. 11, the light-emitting element (e.g., an organic light-emitting diode) may include a first emitting unit EU1 including a first emissive layer EL1 and a second emitting unit EU2 including a second emissive layer EL2 stacked on each other. The charge generation layer CGL may be disposed between the first emitting unit EU1 and the second emitting unit EU2. For example, the light-emitting element (e.g., an organic light-emitting diode) may include a pixel electrode 201, a first emissive layer EL1, a charge generation layer CGL, a second emissive layer EL2, and a common electrode 205 sequentially stacked on one another. A first functional layer and a second functional layer may be disposed under and over the first emissive layer EL1, respectively. A first functional layer and a second functional layer may be disposed under and over the second emissive layer EL2, respectively. The first emissive layer EL1 may be a blue emissive layer, and the second emissive layer EL2 may be a yellow emissive layer.

According to an exemplary embodiment, as shown in FIG. 12, the light-emitting element (e.g., an organic light-emitting diode) may include a first light-emitting unit EU1 including a first emissive layer EL1, a third light-emitting unit EU3 including a first emissive layer EL1, and a second light-emitting unit EU2 including a second emissive layer EL2. The first charge generation layer CGL1 may be disposed between the first emitting unit EU1 and the second emitting unit EU2, and the second charge generation layer CGL2 may be disposed between the second emitting unit EU2 and the third emitting unit EU3. For example, the light-emitting element (e.g., organic light-emitting diode) may include a pixel electrode 201, a first emissive layer EL1, a first charge generation layer CGL1, a second emissive layer EL2, a second charge generation layer CGL2, a first emissive layer EL1, and a common electrode 205, which are stacked on one another in this order. A first functional layer and a second functional layer may be disposed under and over the first emissive layer EL1, respectively. A first functional layer and a second functional layer may be disposed under and over the second emissive layer EL2, respectively. The first emissive layer EL1 may be a blue emissive layer, and the second emissive layer EL2 may be a yellow emissive layer.

According to an exemplary embodiment of the present disclosure, the second emitting unit EU2 of the light-emitting element (e.g., organic light-emitting diode) may further include a third emitting layer EL3 and/or a fourth emitting layer EL4 in direct contact with the second emitting unit EU2 under and/or over the second emitting layer EL2 in addition to the second emitting layer EL2. As used herein, the phrase that the third emitting layer EL3 and/or the fourth emitting layer EL4 are in direct contact with the second emitting unit EU2 means that no other layer is disposed between the second emitting layer EL2 and the third emitting layer EL3 and/or between the second emitting layer EL2 and the fourth emitting layer EL4. The third emissive layer EL3 may be a red emissive layer, and the fourth emissive layer ELA may be a green emissive layer.

For example, as shown in FIG. 13, the light-emitting element (e.g., organic light-emitting diode) may include a pixel electrode 201, a first emissive layer EL1, a first charge generation layer CGL1, a third emissive layer EL3, a second emissive layer EL2, a second charge generation layer CGL2, a first emissive layer EL1, and a common electrode 205, which are stacked on one another in this order. Alternatively, as shown in FIG. 14, the light-emitting element (e.g., organic light-emitting diode) may include a pixel electrode 201, a first emissive layer EL1, a first charge generation layer CGL1, a third emissive layer EL3, a second emissive layer EL2, a fourth emissive layer EL4, a second charge generation layer CGL2, a first emissive layer EL1, and a common electrode 205, which are stacked on one another in this order.

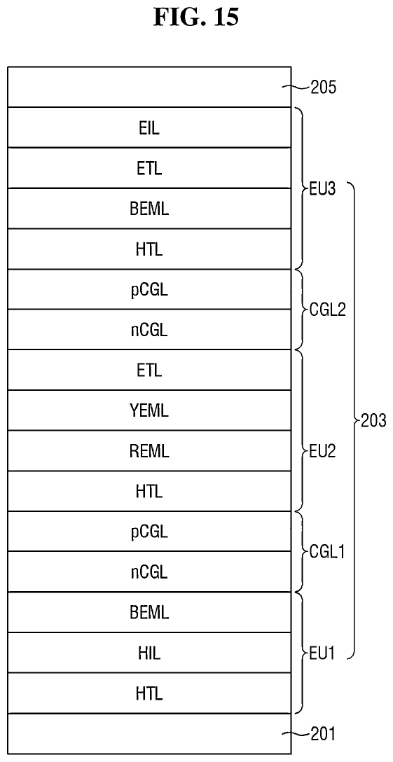

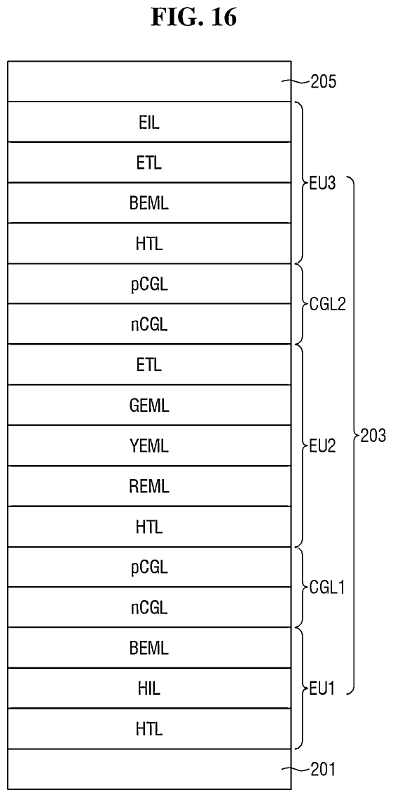

FIG. 15 is a cross-sectional view showing an example of the organic light-emitting diode of FIG. 13. FIG. 16 is a cross-sectional view showing an example of the organic light-emitting diode of FIG. 14.

Referring to FIG. 15, the light-emitting element (e.g., an organic light-emitting diode) may include a first emitting unit EU1, a second emitting unit EU2, and a third emitting unit EU3 stacked on one another in this order. The first charge generation layer CGL1 may be disposed between the first emitting unit EU1 and the second emitting unit EU2, and the second charge generation layer CGL2 may be disposed between the second emitting unit EU2 and the third emitting unit EU3. Each of the first charge generation layer CGL1 and the second charge generation layer CGL2 may include a negative charge generation layer nCGL and a positive charge generation layer pCGL.

The first emitting unit EU1 may include a blue emissive layer BEML. The first emitting unit EU1 may further include a hole injection layer HIL and a hole transport layer HTL disposed between the pixel electrode 201 and the blue emissive layer BEML. According to an exemplary embodiment of the present disclosure, a p-doped layer may be further included between the hole injection layer HIL and the hole transport layer HTL. The p-doped layer may be formed by doping the hole injection layer HIL with a p-type doping material. According to an exemplary embodiment of the present disclosure, at least one of a blue light auxiliary layer, an electron blocking layer and a buffer layer may be further included between the blue emissive layer BEML and the hole transport layer HTL. The blue light auxiliary layer can increase the emission efficiency of the blue emissive layer BEML. The blue light auxiliary layer can increase the emission efficiency of the blue emissive layer BEML by adjusting the hole charge balance. The electron blocking layer may be used to prevent injection of electrons into the hole transport layer HTL. The buffer layer may be used to compensate for a resonance distance according to a wavelength of light emitted from the emissive layer.

The second emitting unit EU2 may include a yellow emissive layer YEML and a red emissive layer REML directly in contact with the yellow emissive layer YEML under the yellow emissive layer YEML. The second emitting unit EU2 may further include a hole transport layer HTL disposed between the positive charge generation layer pCGL of the first charge generation layer CGL1 and the red emissive layer REML, and an electron transport layer ETL between the yellow emissive layer YEML and the negative charge generation layer nCGL of the second charge generation layer CGL2.

The third emitting unit EU3 may include a blue emissive layer BEML. The third emitting unit EU3 may further include a hole transport layer HTL disposed between the positive charge generation layer pCGL of the second charge generation layer CGL2 and the blue emissive layer BEML. The third emitting unit EU3 may further include an electron transport layer ETL and an electron injection layer EIL between the blue emissive layer BEML and the common electrode 205. The electron transport layer ETL may include a single layer or multiple layers. According to an exemplary embodiment of the present disclosure, at least one of a blue light auxiliary layer, an electron blocking layer and a buffer layer may be further included between the blue emissive layer BEML and the hole transport layer HTL. At least one of the hole blocking layer and the buffer layer may be further included between the blue emissive layer BEML and the electron transport layer ETL. The hole blocking layer may be used to prevent injection of holes into the electron transport layer ETL.

The light-emitting element (e.g., organic light-emitting diode) shown in FIG. 16 is substantially identical to the light-emitting element (e.g., organic light-emitting diode) shown in FIG. 15 except for a stack structure of a second emitting unit EU2. Referring to FIG. 16, the second emitting unit EU2 may include a yellow emissive layer YEML; a red emissive layer REML directly in contact with the yellow emissive layer YEML under the yellow emissive layer YEML; and a green emissive layer GEML directly in contact with the yellow emissive layer YEML over the yellow emissive layer YEML. The second emitting unit EU2 may further include a hole transport layer HTL between the positive charge generation layer pCGL of the first charge generation layer CGL1 and the red emissive layer REML, and an electron transport layer ETL between the green emissive layer GEML and the negative charge generation layer nCGL of the second charge generation layer CGL2.

In concluding the detailed description, those skilled in the art will appreciate that many variations and modifications can be made to the preferred embodiments without substantially departing from the principles of the present inventive concept. Therefore, the disclosed preferred embodiments of the inventive concept are used in a generic and descriptive sense only and not for purposes of limitation.

What is claimed is:

1. A display device comprising:
a substrate;
a first pixel electrode and a second pixel electrode disposed on the substrate;
a first light-providing layer disposed on the first pixel electrode;
a second light-providing layer disposed on the second pixel electrode;
a common electrode disposed on the first light-providing layer and the second light-providing layer; and
a current capture layer disposed between the first pixel electrode and the second pixel electrode in a plan view.

2. The display device of claim 1, wherein a capture voltage applied to the current capture layer is lower than a pixel voltage applied to the first pixel electrode.

3. The display device of claim 2, wherein the capture voltage is identical to a common voltage applied to the common electrode.

4. The display device of claim 1, further comprising:
a bank overlapping the current capture layer in a plan view and defining a first emission area of the first pixel electrode and a second emission area of the second pixel electrode.

5. The display device of claim 4, further comprising:
a light-blocking layer overlapping the current capture layer in a plan view.

6. The display device of claim 5, further comprising:
a separator disposed on the bank to overlap the light-blocking layer in a plan view.

7. The display device of claim 6, wherein the current capture layer overlaps with the bank, the separator, and the light-blocking layer.

8. The display device of claim 5, further comprising:
a separator overlapping the light-blocking layer,
wherein the bank includes holes formed through the bank.

9. The display device of claim 8, further comprising an insulating layer disposed under the bank and including grooves disposed in areas corresponding to the holes.

10. The display device of claim 9, wherein the separation layer fills the holes and the grooves.

11. The display device of claim 10, wherein portions of the separation layer filling the holes and the grooves cover sidewalls of the current capture layer.

12. The display device of claim 4, further comprising:
a first color filter overlapping the first emission area; and
a second color filter overlapping the second emission area.

13. The display device of claim 1, wherein the current capture layer has a shape surrounding each of the first pixel electrode and the second pixel electrode, and
wherein a portion of the current capture layer is disposed between the first pixel electrode and the second pixel electrode.

14. The display device of claim 13, wherein the current capture layer comprises:
a first extended portion extending in a first direction; and
a second extended portion extending in a second direction crossing the first direction.

15. The display device of claim 14, wherein the current capture layer defines a plurality of open areas surrounded by the first extended portion and the second extended portion, and
wherein the first pixel electrode and the second pixel electrode are disposed in corresponding open areas.

16. The display device of claim 1, wherein the current capture layer is connected directly to at least one of the first light-providing layer and the second light-providing layer.

17. The display device of claim 16, wherein the current capture layer comprises:
a support layer disposed between the first pixel electrode and the second pixel electrode; and
a connection layer extending from the support layer, disposed between the first light-providing layer and the second light-providing layer, and connected to at least one of the first light-providing layer and the second light-providing layer.

18. The display device of claim 1, wherein each of the first light-providing layer and the second light-providing layer comprises a plurality of light-emitting units providing lights of different colors.

19. A display device comprising:
a substrate; and
a plurality of light-emitting elements disposed on the substrate, each of the plurality of light-emitting elements including:
a pixel electrode and a current capturing layer disposed on a same plane and including a same material, the current capturing layer completely surrounding the pixel electrode,
a bank disposed on the pixel electrode to cover edges of the pixel electrode and on the current capturing layer to cover the current capturing layer,
a light providing layer disposed on the pixel electrode, and
a common electrode disposed on the light-providing layer.

20. The display device of claim 19, wherein the bank completely covers a top surface and sidewalls of the current capturing layer.
